(19) United States
(12) Patent Application Publication
(10) Pub. No.: US 2026/0047455 A1
(43) Pub. Date: Feb. 12, 2026

(54) SEMICONDUCTOR PACKAGE WITH SUBSTRATE CAVITIES

(71) Applicant: SAMSUNG ELECTRONICS CO., LTD., Suwon-si (KR)

(72) Inventors: Jae-Ean Lee, Suwon-si (KR); Dongwon Kang, Suwon-si (KR); Changyeon Song, Suwon-si (KR)

(73) Assignee: SAMSUNG ELECTRONICS CO., LTD., Suwon-si (KR)

(21) Appl. No.: 19/081,675

(22) Filed: Mar. 17, 2025

(30) Foreign Application Priority Data
Aug. 9, 2024 (KR) 10-2024-0106828

(51) Int. Cl. H01L 23/538; H01L 21/48; H01L 23/00; H01L 23/13; H01L 23/367; H01L 25/10; H01L 25/18; H10B 80/00; H10D 80/30

(52) U.S. Cl. CPC H01L 23/5383; H01L 23/13; H01L 23/3677; H01L 23/5385; H01L 23/5386; H01L 25/105; H01L 25/18; H01L 21/4857; H01L 24/08; H01L 24/16; H01L 24/32; H01L 24/73; H01L 2224/08235; H01L 2224/16227; H01L 2224/16238; H01L 2224/32145; H01L 2224/32225; H01L 2224/32245; H01L 2224/73204; H01L 2224/73253; H01L 2225/1023; H01L 2225/1094; H01L 2924/1431; H10B 80/00; H10D 80/30

(57) ABSTRACT

Provided is a semiconductor package including: a substrate including a first surface a and second surface opposite to the first surface, the substrate further including a first cavity extending from the first surface to the second surface; first and second lower semiconductor chips, wherein the first and second lower semiconductor chips are vertically stacked in the first cavity; a first redistribution substrate on the first surface of the substrate; a first upper semiconductor chip on the first redistribution substrate; a second upper semiconductor chip on the first redistribution substrate and horizontally spaced apart from the first upper semiconductor chip; and a first bridge chip in the first redistribution substrate that connects the first and second upper semiconductor chips, wherein the first lower semiconductor chip is spaced apart from the first redistribution substrate, and wherein the second lower semiconductor chip is directly connected to the first redistribution substrate.

### CROSS-REFERENCE TO RELATED APPLICATION

This application claims priority to Korean Patent Application No. 10-2024-0106828, filed on Aug. 9, 2024, in the Korean Intellectual Property Office, the entire contents of which are hereby incorporated by reference.

### BACKGROUND

### 1. Field

The present disclosure relates to a semiconductor package.

### 2. Description of Related Art

A semiconductor package generally includes an integrated circuit chip that is provided to be used as a part of an electronic product. In general, the semiconductor package includes a printed circuit board (PCB) and a semiconductor chip which is mounted on the PCB and is electrically connected to the PCB using bonding wires or bumps. As the electronics industry has developed, many studies are being conducted to improve reliability of semiconductor packaging and to reduce the size of semiconductor packaging.

### SUMMARY

Provided is a semiconductor package with improved electric performance and electric reliability.

According to an aspect of the disclosure, a semiconductor package includes: a substrate including a first surface and a second surface, wherein the second surface is opposite to the first surface, and wherein the substrate further includes a first cavity extending from the first surface to the second surface; a first lower semiconductor chip and a second lower semiconductor chip, wherein the first and the second lower semiconductor chips are vertically stacked in the first cavity; a first redistribution substrate on the first surface of the substrate; a first upper semiconductor chip on the first redistribution substrate; a second upper semiconductor chip on the first redistribution substrate and horizontally spaced apart from the first upper semiconductor chip; and a first bridge chip in the first redistribution substrate, wherein the first bridge chip connects the first upper semiconductor chip to the second upper semiconductor chip, wherein the first lower semiconductor chip is spaced apart from the first redistribution substrate, and wherein the second lower semiconductor chip is directly connected to the first redistribution substrate.

According to an aspect of the disclosure, a semiconductor package includes: a substrate including a first surface and a second surface, wherein the second surface is opposite to the first surface, and wherein the substrate further includes a first cavity extending from the first surface to the second surface; a first lower semiconductor chip and a second lower semiconductor chip, wherein the first and the second lower semiconductor chips are vertically stacked in the first cavity; a first redistribution substrate on the first surface of the substrate; a first upper semiconductor chip on the first redistribution substrate; a second upper semiconductor chip on the first redistribution substrate and horizontally spaced apart from the first upper semiconductor chip; a bridge chip in the first redistribution substrate, wherein the bridge chip connects the first upper semiconductor chip to and the second upper semiconductor chip; and a second redistribution substrate on the second surface.

According to an aspect of the disclosure, a semiconductor package includes: a substrate including a first surface and a second surface, wherein the second surface is opposite to the first surface, and wherein the substrate further includes a cavity extending from the first surface to the second surface; a first lower semiconductor chip and a second lower semiconductor chip, wherein the first and the second lower semiconductor chips are vertically stacked in the cavity; a first redistribution substrate on the first surface of the substrate and on the second lower semiconductor chip; a second redistribution substrate on the second surface of the substrate and on the first lower semiconductor chip; a gapfill insulating layer between the substrate and the first redistribution substrate and between the substrate and the first and the second lower semiconductor chips; a first upper semiconductor chip on the first redistribution substrate; a second upper semiconductor chip on the first redistribution substrate and horizontally spaced apart from the first upper semiconductor chip; conductive bumps connecting the first upper semiconductor chip to the first redistribution substrate and connecting the second upper semiconductor chip to the first redistribution substrate; a bridge chip in the first redistribution substrate, wherein the bridge chip connects the first upper semiconductor chip to the second upper semiconductor chip; and a mold layer on the first redistribution substrate and on at least a portion of a side surface of the first upper semiconductor chip and at least a portion of a side surface of the second upper semiconductor chip.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a cross-sectional view illustrating a semiconductor package according to one or more embodiments of the disclosure;

FIG. 2 is a cross-sectional view illustrating a semiconductor package according to one or more embodiments of the disclosure;

FIG. 3 is a cross-sectional view illustrating a semiconductor package according to one or more embodiments of the disclosure; and

FIGS. 4 through 15 are cross-sectional views illustrating a method of fabricating a semiconductor package, according to one or more embodiments of the disclosure.

### DETAILED DESCRIPTION

Example embodiments of the disclosures will now be described more fully with reference to the accompanying drawings, in which example embodiments are shown.

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

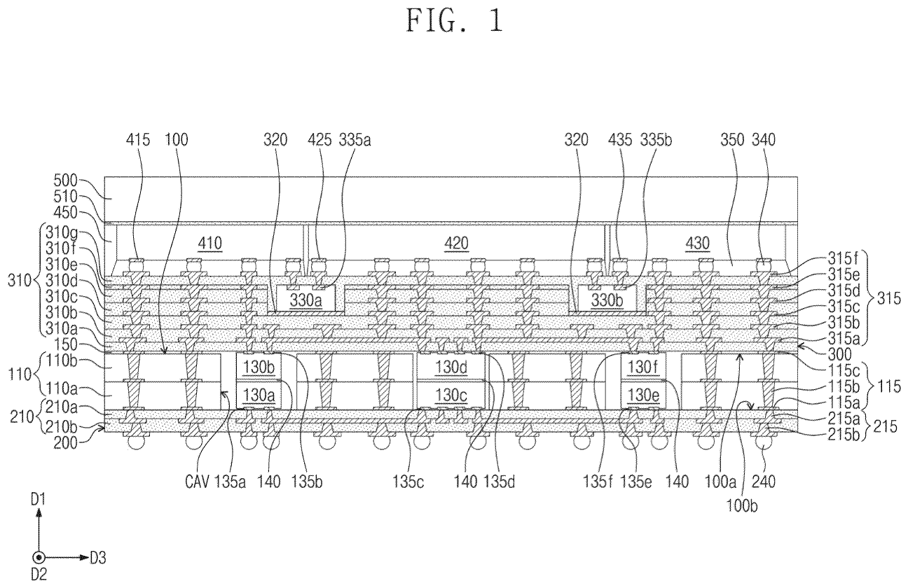

FIG. 1 is a cross-sectional view illustrating a semiconductor package according to one or more embodiments of the disclosure.

Referring to FIG. 1, a semiconductor package according to one or more embodiments of the disclosure may include a substrate 100, a first redistribution substrate 300, and a second redistribution substrate 200. Lower semiconductor chips 130a, 130b, 130c, 130d, 130e, and 130f, first to third upper semiconductor chips 410, 420, and 430, and a bridge chip 330 may be provided in the semiconductor package.

The substrate 100 may have a first surface 100a and a second surface 100b, which are opposite to each other. The first surface 100a may be a surface of the substrate 100 facing the first redistribution substrate 300 and may be referred to as a top surface of the substrate 100. The second surface 100b may be a surface of the substrate 100 that is opposite to the first surface 100a and may be referred to as a bottom surface of the substrate 100. In one or more embodiments, the second surface 100b may be flat. The substrate 100 may include insulating patterns 110 that are stacked in a first direction D1.

In the present disclosure, the first direction D1 may be perpendicular to the second surface 100b of the substrate 100. A second direction D2 and a third direction D3 may be direction, which are parallel to the second surface 100b of the substrate 100 and are perpendicular to each other.

The substrate 100 may be a cavity substrate, in which the lower semiconductor chips 130a, 130b, 130c, 130d, 130e, and 130f are placed. In one or more embodiments, the substrate 100 may be a coreless substrate which is formed in an embedded trace substrate (ETS) manner. In another embodiment, the substrate 100 may be a printed circuit board (PCB).

The substrate 100 may include cavities CAV, the insulating patterns 110, and interconnection patterns 115, which are formed in the insulating patterns 110. The lower semiconductor chips 130a, 130b, 130c, 130d, 130e, and 130f may be placed in the cavities CAV of the substrate 100. In one or more embodiments, each of the cavities CAV may be a hole, which is extended from the first surface 100a to the second surface 100b to penetrate the substrate 100. In the substrate 100, the cavities CAV may be formed to be spaced apart from each other in a horizontal direction (e.g., the second or third direction D2 or D3). In the present specification, three cavities CAV, which are sequentially arranged in the third direction D3, will be referred to as first to third cavities CAV, for convenience in description.

The lower semiconductor chips 130a, 130b, 130c, 130d, 130e, and 130f may be placed in the cavities CAV. In each of the cavities CAV, the lower semiconductor chips 130a, 130b, 130c, 130d, 130e, and 130f may be vertically stacked. For example, the first and second lower semiconductor chips 130a and 130b may be vertically stacked in the first cavity CAV, the third and fourth lower semiconductor chips 130c and 130d may be vertically stacked in the second cavity CAV, and the fifth and sixth lower semiconductor chips 130e and 130f may be vertically stacked in the third cavity CAV. The first to sixth lower semiconductor chips 130a, 130b, 130c, 130d, 130e, and 130f may be memory chips of the same kind or may be semiconductor chips of different kinds. In one or more embodiments, at least one of the lower semiconductor chips 130a, 130b, 130c, 130d, 130e, and 130f may be a computer express link (CXL) chip or a power management IC (PMIC). In another embodiment, at least one of the lower semiconductor chips 130a, 130b, 130c, 130d, 130e, and 130f may be a logic chip, a memory chip, or a capacitor. The memory chip may be a volatile memory chip (e.g., a dynamic random access memory (DRAM) chip or a static random access memory (SRAM) chip) or a nonvolatile memory chip (e.g., phase-change random access memory (PRAM) chip, a magnetoresistive random access memory (MRAM) chip, a ferroelectric random access memory (FeRAM) chip, or a resistive random access memory (RRAM) chip). The logic chip may be a micro-processor (e.g., a central processing unit (CPU), a graphics processing unit (GPU), or an application processor (AP)), an analogue device, or a digital signal processor.

Each of the lower semiconductor chips 130a, 130b, 130c, 130d, 130e, and 130f may include a front surface and a rear surface which are opposite to each other. The front surfaces of the lower semiconductor chips 130a, 130b, 130c, 130d, 130e, and 130f may be active surfaces, on which fine circuits are formed. The front surfaces of the second, fourth, and sixth lower semiconductor chips 130b, 130d, and 130f may face the first redistribution substrate 300. The second, fourth, and sixth lower semiconductor chips 130b, 130d, and 130f may be connected to the first redistribution substrate 300 and may be spaced apart from the second redistribution substrate 200. By contrast, the front surfaces of the first, third, and fifth lower semiconductor chips 130a, 130c, and 130e may face the second redistribution substrate 200. The first, third, and fifth lower semiconductor chips 130a, 130c, and 130e may be connected to the second redistribution substrate 200 and may be spaced apart from the first redistribution substrate 300. In other words, the first lower semiconductor chip 130a may be placed in a face-down manner, with its front surface facing downward, and the second lower semiconductor chip 130b may be placed in a face-up manner, with its front surface facing upward. Similarly, the third and fifth lower semiconductor chips 130c and 130e may be placed in a face-down manner, and the fourth and sixth lower semiconductor chips 130d and 130f may be placed in a face-up manner.

Adhesive layers 140 may be respectively disposed between the first, third, and fifth lower semiconductor chips 130a, 130c, and 130e in the face-down state and the second, fourth, and sixth lower semiconductor chips 130b, 130d, and 130f in the face-up state. For example, the adhesive layers 140 may be respectively disposed between the first lower semiconductor chip 130a and the second lower semiconductor chip 130b, between the third lower semiconductor chip 130c and the fourth lower semiconductor chip 130d, and between the fifth lower semiconductor chip 130e and the sixth lower semiconductor chip 130f. In other words, the adhesive layers 140 may be respectively disposed between the rear surfaces of the lower semiconductor chips 130a, 130b, 130c, 130d, 130e, and 130f to attach the lower semiconductors 130a, 130b, 130c, 130d, 130e, and 130f to each other. In one or more embodiments, the adhesive layer 140 may include an adhesive polymer material.

First to sixth lower chip pads 135a, 135b, 135c, 135d, 135e, and 135f may be provided on the front surfaces of the lower semiconductor chips 130a, 130b, 130c, 130d, 130e, and 130f, respectively. Each of the first to sixth lower chip pads 135a, 135b, 135c, 135d, 135e, and 135f may be used to connect a corresponding one of the lower semiconductor chips 130a, 130b, 130c, 130d, 130e, and 130f to the first or second redistribution substrates 100 and 200.

The insulating patterns 110 may include first and second insulating patterns 110a and 110b, which are vertically stacked (e.g., in the first direction D1). The first insulating pattern 110a may be the lowermost insulating layer, which is closest to the second surface 100b of the substrate 100 (i.e., the bottom surface of the substrate 100), and the second insulating pattern 110b may be the uppermost insulating layer, which is closest to the first surface 100a of the substrate 100 (i.e., the top surface of the substrate 100). The first surface 100a of the substrate 100 may be a top surface of the second insulating pattern 110b, and the second surface 100b of the substrate 100 may be a bottom surface of the first insulating pattern 110a. In one or more embodiments, the first insulating pattern 110a may have side surfaces facing side surfaces of the first, third, and fifth lower semiconductor chips 130a, 130c, and 130e. The second insulating pattern 110b may have side surfaces facing side surfaces of the second, fourth, and sixth lower semiconductor chips 130b, 130d, and 130f.

FIG. 1 illustrates an example, in which the insulating patterns 110 are provided to form a double-layered structure, but the disclosure is not limited to this example; for example, three or more insulating patterns 110 may be provided to form a multi-layered structure with three or more layers.

In one or more embodiments, the insulating patterns 110 may include a prepreg. In addition, the insulating patterns 110 may be formed of at least one of phenolic resin, epoxy resin, or polyimide. The insulating patterns 110 may include at least one of, for example, frame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

The interconnection patterns 115 may be formed to penetrate the substrate 100 from the first surface 100a to the second surface 100b and may be used as an electric connection path. The interconnection patterns 115 may electrically connect the first redistribution substrate 300 to the second redistribution substrate 200. The interconnection patterns 115 may include at least one of copper, nickel, stainless steel, or beryllium copper.

The interconnection patterns 115 may include an interconnection line 115a, an interconnection via 115b, and an interconnection pad 115c. In one or more embodiments, the interconnection patterns 115 may have a multi-layered structure, in which two or more interconnection lines 115a or two or more interconnection vias 115b are alternatively stacked. The interconnection via 115b may be extended to penetrate at least one of the first and second insulating patterns 110a and 110b. The interconnection vias 115b may electrically connect the interconnection lines 115a, which are placed at different levels in the vertical direction (e.g., the third direction D3), to each other. For example, the interconnection via 115b may electrically connect the interconnection line 115a in the first insulating pattern 110a to the interconnection line 115a in the second insulating pattern 110b. The interconnection pad 115c may be disposed on the second insulating pattern 110b to connect the interconnection via 115b to the first redistribution substrate 300. The interconnection pad 115c may protrude above the second insulating pattern 110b. In one or more embodiments, at least a portion of the interconnection line 115a and at least a portion of the interconnection via 115b may be provided to form a single object.

A gapfill insulating layer 150 may cover the first surface 100a and the side surface of the substrate 100. The gapfill insulating layer 150 may be provided to fill the cavities CAV of the substrate 100 and enclose the lower semiconductor chips 130a, 130b, 130c, 130d, 130e, and 130f. In one or more embodiments, a top surface of the gapfill insulating layer 150 may be coplanar with a top surface of the interconnection pad 115c.

The gapfill insulating layer 150 may be formed of or include at least one of thermosetting resins (e.g., an epoxy resin), thermoplastic resins (e.g., polyimide), or thermosetting or thermoplastic resins containing reinforcing elements (e.g., organic fillers) (in particular, Ajinomoto build-up film (ABF), FR-4, or BT), but the disclosure is not limited to this example. In one or more embodiments, the gapfill insulating layer 150 may be formed of a molding material (e.g., an epoxy molding compound (EMC)) or a photoimageable material (e.g., photoimageable encapsulant (PIE)). In another embodiment, a portion of the gapfill insulating layer 150 may be formed of or include at least one of silicon oxide, silicon nitride, or silicon oxynitride.

The first redistribution substrate 300 may be provided on the first or top surface 100a of the substrate 100. The first redistribution substrate 300 may be a redistribution substrate that is fabricated through a redistribution process. The first redistribution substrate 300 may be disposed on the gapfill insulating layer 150 and may be directly connected to the interconnection pad 115c and the second, fourth, and sixth lower chip pads 135b, 135d, and 135f.

The first redistribution substrate 300 may include a first redistribution insulating layer 310 and first redistribution conductive pattern 315. The substrate 100, the first to third upper semiconductor chips 410, 420, and 430, the second, fourth, and sixth lower semiconductor chips 130b, 130d, and 130f, and first and second bridge chips 330a and 330b may be electrically connected to each other through the first redistribution conductive pattern 315 of the first redistribution substrate 300.

The first redistribution insulating layer 310 may include first to seventh upper insulating layers 310a, 310b, 310c, 310d, 310e, 310f, and 310g which are stacked in the first direction D1. A top surface of the seventh upper insulating layer 310g, which is the uppermost one of the first to seventh upper insulating layers 310a, 310b, 310c, 310d, 310e, 310f, and 310g, may correspond to a top surface of the first redistribution substrate 300. A bottom surface of the first upper insulating layer 310a, which is the lowermost one of the first to seventh upper insulating layers 310a, 310b, 310c, 310d, 310e, 310f, and 310g, may correspond to a bottom surface of the first redistribution substrate 300. In one or more embodiments, the first redistribution insulating layer 310 may be formed of or include at least one of photo imageable dielectric (PID) materials or photosensitive polyimide (PSPI) materials.

The first redistribution conductive pattern 315 may be provided in the first redistribution insulating layer 310 to penetrate the first redistribution substrate 300 from the top surface to the bottom surface and may be used as an electric connection path passing through the first redistribution substrate 300. The first redistribution conductive pattern 315 may electrically connect the interconnection patterns 115 to the first to third upper semiconductor chips 410, 420, and 430 and may electrically connect the second, fourth, and sixth lower semiconductor chips 130b, 130d, and 130f to the first to third upper semiconductor chips 410, 420, and 430. The first redistribution conductive pattern 315 may include first to sixth upper conductive patterns 315a, 315b, 315c, 315d, 315e, and 315f. The first to sixth upper conductive patterns 315a, 315b, 315c, 315d, 315e, and 315f may be provided to at least partially penetrate the first to seventh upper insulating layers 310a, 310b, 310c, 310d, 310e, 310f, and 10g, respectively.

Some of the first upper conductive patterns 315a may be used to electrically connect the second lower semiconductor chip 130b to the fourth lower semiconductor chip 130d and to electrically connect the fourth lower semiconductor chip 130d to the sixth lower semiconductor chip 130f. For example, at least one of the first upper conductive patterns 315a may be used to connect the second lower chip pad 135b to the fourth lower chip pad 135d, and at least one of the first upper conductive patterns 315a may be used to connect the fourth lower chip pad 135d to the sixth lower chip pad 135f.

Each of the first to sixth upper conductive patterns 315a, 315b, 315c, 315d, 315e, and 315f may include an upper line pattern, which is extended in a horizontal direction, and an upper via pattern, which is extended from the upper line pattern in the first direction D1. The upper via patterns may have a tapered shape whose horizontal width increases in an upward direction. For example, the width of the upper via pattern may increase as a distance to the first to third upper semiconductor chips 410, 420, and 430 decreases. In one or more embodiments, the first redistribution conductive pattern 315 may be formed of or include at least one of metallic materials (e.g., copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru)) or alloys of the metallic materials, but the disclosure is not limited to these examples. As an example, the first redistribution conductive pattern 315 may be provided to include a seed layer (e.g., of copper, titanium, titanium nitride, or titanium tungsten) and a metal or metal alloy layer stacked on the seed layer.

FIG. 1 illustrates an example of the first redistribution insulating layer 310, which is composed of seven insulating layers, but the disclosure is not limited to this example; for example, the first redistribution insulating layer 310 may have a multi-layered structure with seven or more layers, or seven or fewer layers. Furthermore, the first redistribution conductive pattern 315 may also be configured to further include at least one conductive pattern, or at least one conductive pattern of them may be omitted.

The first and second bridge chips 330a and 330b may be buried in the first redistribution substrate 300. For example, the first and second bridge chips 330a and 330b may be horizontally spaced apart from the fourth to sixth upper insulating layers 310d, 310e, and 310f and may have top and side surfaces, which are covered with the seventh upper insulating layer 310g, but the disclosure is not limited to this example. Each of the first and second bridge chips 330a and 330b may be disposed on a stopper metal layer 320.

The first and second bridge chips 330a and 330b may be electrically connected to the sixth upper conductive pattern 315f of the first redistribution conductive pattern 315. For example, first and second bridge coupling terminals 335a and 335b, which are respectively provided on the top surfaces of the first and second bridge chips 330a and 330b, may be electrically connected to the sixth upper conductive patterns 315f, respectively. The sixth upper conductive patterns 315f, which are connected to the first bridge coupling terminals 335a, may be connected to the first and second upper semiconductor chips 410 and 420. The sixth upper conductive patterns 315f, which are connected to the second bridge coupling terminals 335b, may be connected to the second and third upper semiconductor chips 420 and 430. In other words, the first bridge chip 330a may electrically connect the first upper semiconductor chip 410 to the second upper semiconductor chip 420, and the second bridge chip 330b may electrically connect the second upper semiconductor chip 420 to the third upper semiconductor chip 430.

In one or more embodiments, the first upper semiconductor chip 410 and the second upper semiconductor chip 420 may include first upper chip pads 415 and second upper chip pads 425, respectively, and here, in the case where the first and second upper chip pads 415 and 425 have different pitches, the first bridge chip 330a may include a bridge circuit, which is configured to have pitches corresponding to the pitches of the first and second upper chip pads 415 and 425. Accordingly, the first and second upper semiconductor chips 410 and 420 may be electrically connected to each other through the first bridge chip 330a. Similarly, the second bridge chip 330b may include a bridge circuit, which is configured to have pitches corresponding to the pitches of the second and third upper chip pads 425 and 435, and the second and third upper semiconductor chips 420 and 430 may be electrically connected to each other through the second bridge chip 330b. In other words, the first and second bridge chips 330a and 330b may be used as a bridge electrically connecting the upper semiconductor chips 410, 420, and 430, which are mounted on the top surface of the first redistribution substrate 300, to each other. In one or more embodiments, each of the first and second bridge chips 330a and 330b may include a silicon substrate, but the disclosure is not limited to this example.

The stopper metal layers 320 may be buried in the first redistribution substrate 300. When viewed in a plan view, each of the stopper metal layers 320 may be partially overlapped with two chips of the first to third upper semiconductor chips 410, 420, and 430. As an example, the stopper metal layers 320 may be respectively disposed below the first and second upper semiconductor chips 410 and 420 and below the second and third upper semiconductor chips 420 and 430. In one or more embodiments, the stopper metal layers 320 may be formed of or include a material (e.g., copper) having a resistant property to a laser beam. The stopper metal layer 320 may be formed using a plating method. For example, the stopper metal layer 320 may be formed by an electroplating method, an electroless plating method, or an immersion plating method.

The stopper metal layers 320 may have a rectangular plate shape, but the disclosure is not limited to this example. In one or more embodiments, when viewed in a cross-sectional view, a length of the stopper metal layers 320 in the third direction D3 may be larger than a length of the first and second bridge chips 330a and 330b in the third direction D3.

The first to third upper semiconductor chips 410, 420, and 430 may be mounted on the top surface of the first redistribution substrate 300. Each of the first to third upper semiconductor chips 410, 420, and 430 may have an active surface and an inactive surface, which are opposite to each other, and furthermore, the first to third upper semiconductor chips 410, 420, and 430 may include the upper chip pads 415, 425, and 435, which are respectively provided on the active surfaces thereof. The first to third upper semiconductor chips 410, 420, and 430 may be mounted on the top surface of the first redistribution substrate 300 through conductive bumps 340. The conductive bumps 340 may be provided in the form of pillars, balls, or solder layers.

The first to third upper semiconductor chips 410, 420, and 430 may be spaced apart from each other in a horizontal direction (e.g., in the second or third direction D2 or D3), on the top surface of the first redistribution substrate 300. In one or more embodiments, the first to third upper semiconductor chips 410, 420, and 430 may be sequentially mounted on the first redistribution substrate 300 in the third direction D3.

An under-fill layer 350 may be interposed between the first to third upper semiconductor chips 410, 420, and 430 and the first redistribution substrate 300. The under-fill layer 350 may be provided to enclose the conductive bumps 340. In one or more embodiments, the under-fill layer 350 may include an epoxy resin.

FIG. 1 illustrates an example, in which the first to third upper semiconductor chips 410, 420, and 430 are mounted on the top surface of the first redistribution substrate 300 in a flip chip manner, but the method of mounting the first to third upper semiconductor chips 410, 420, and 430 on the top surface of the first redistribution substrate 300 is not limited to this example.

The first to third upper semiconductor chips 410, 420, and 430 may be semiconductor chips. Each of the first to third upper semiconductor chips 410, 420, and 430 may be a memory chip or a logic chip. As an example, the first upper semiconductor chip 410 and the third upper semiconductor chip 430 may be memory chips, and the second upper semiconductor chip 420 may be a logic chip. The logic and memory chips may be the same or similar to those described above, and a detailed description thereof will be omitted.

A mold layer 450 may be provided on the top surface of the first redistribution substrate 300 to enclose the first to third upper semiconductor chips 410, 420, and 430. A top surface of the mold layer 450 may be coplanar with the top surfaces of the first to third upper semiconductor chips 410, 420, and 430. In one or more embodiments, the mold layer 450 may be formed of or include at least one of insulating polymers or epoxy resins.

A heat dissipation plate 500 and a thermally conductive element 510 may be disposed on the first to third upper semiconductor chips 410, 420, and 430. The heat dissipation plate 500 may be configured to dissipate heat, which is generated from the first to third upper semiconductor chips 410, 420, and 430, to the outside. In one or more embodiments, the heat dissipation plate 500 may be a heat sink, a heat spreader, a heat pipe, or a liquid cooled cold plate. A thickness of the heat-dissipation plate 500 in the first direction D1 may range from 2 mm to 4 mm.

The thermally conductive element 510 may be interposed between the first to third upper semiconductor chips 410, 420, and 430 and the heat-dissipation plate 500 and may be used to attach the heat dissipation plate 500 to the first to third upper semiconductor chips 410, 420, and 430. The thermally conductive element 510 may be formed of an electrically insulating material or may include an electrically insulating material, and thus, the first to third upper semiconductor chips 410, 420, and 430 and the thermally conductive element 510 may be electrically disconnected from each other. In one or more embodiments, the thermally conductive element 510 may include an insulating base layer (e.g., an epoxy resin) and heat-dissipation fillers therein. In one or more embodiments, the thermally conductive element 510 may include at least one of mineral oil, grease, gap filler putty, phase change gel, phase change material pads, or particle filled epoxy. In one or more embodiments, the thermally conductive element 510 may have thermal conductivity ranging from 3 W/m·K to 4 W/m·K.

The first redistribution substrate 300 may be provided on the first or top surface 100a of the substrate 100. The second redistribution substrate 200 may be a redistribution substrate that is fabricated through a redistribution process. The first redistribution substrate 300 may be disposed below the substrate 100 and may be connected to the lowermost interconnection line 115a and the first, third, and fifth lower chip pads 135a, 135c, and 135e.

The second redistribution substrate 200 may include a second redistribution insulating layer 210 and second redistribution conductive patterns 215. The substrate 100 and the first, third, and fifth lower semiconductor chips 130a, 130c, and 130e may be electrically connected to each other through the second redistribution conductive patterns 215 of the second redistribution substrate 200.

The second redistribution insulating layer 210 may include first and second lower insulating layers 210a and 210b, which are sequentially stacked on the second surface 100b of the substrate 100 in the first direction D1. In one or more embodiments, the first and second lower insulating layers 210a and 210b may be formed of or include at least one of photo imageable dielectric (PID) materials or photosensitive polyimide (PSPI) materials.

The second redistribution conductive patterns 215 may be provided in the second redistribution insulating layer 210 to penetrate the second redistribution substrate 200 and may be used as an electric connection path passing through the second redistribution insulating layer 210. The interconnection patterns 115, the first, third, and fifth lower semiconductor chips 130a, 130c, and 130e, and the first, third, and fifth lower semiconductor chips 130a, 130c, and 130e may be electrically connected to each other through the second redistribution conductive patterns 215. The second redistribution conductive patterns 215 may include first and second lower conductive patterns 215a and 215b. The first and second lower conductive patterns 215a and 215b may be provided to at least partially penetrate the first and second lower insulating layers 210a and 210b, respectively.

Some of the first lower conductive patterns 215a may electrically connect the first lower semiconductor chip 130a to the third lower semiconductor chip 130c and may electrically connect the third lower semiconductor chip 130c to the fifth lower semiconductor chip 130e. In other words, at least one of the first lower conductive patterns 215a may be used to connect the first lower chip pad 135a to the third lower chip pad 135c, and at least one of the first lower conductive patterns 215a may be used to connect the third lower chip pad 135c to fifth lower chip pad 135e.

Each of the first and second lower conductive patterns 215a and 215b may include a lower line pattern, which is extended in a horizontal direction, and a lower via pattern, which is extended from the lower line pattern in the first direction D1. The lower via patterns may have a tapered shape whose horizontal width increases in a downward direction. For example, the width of the lower via pattern may increase as a distance from the substrate 100 increases. In one or more embodiments, the second redistribution conductive patterns 215 may be formed of or include at least one of metallic materials (e.g., copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru)) or alloys of the metallic materials, but the disclosure is not limited to these examples. As an example, the second redistribution conductive patterns 215 may be provided to include a seed layer (e.g., of copper, titanium, titanium nitride, or titanium tungsten) and a metal or metal alloy layer stacked on the seed layer.

FIG. 1 illustrates an example of the second redistribution insulating layer 210, which is composed of two insulating layers, but the disclosure is not limited to this example; for example, the second redistribution insulating layer 210 may have a multi-layered structure with two or more layers. Furthermore, the second redistribution conductive patterns 215 may also be configured to further include at least one conductive pattern.

An outer coupling terminal 240 may be disposed below the second redistribution substrate 200. The outer coupling terminal 240 may be used to connect the semiconductor package electrically and physically to an external device, on which the semiconductor package is mounted. The outer coupling terminal 240 may be electrically connected to the second redistribution conductive patterns 215. In one or more embodiments, the outer coupling terminal 240 may be solder balls or solder bumps.

In the semiconductor package according to one or more embodiments of the disclosure, since the lower semiconductor chips 130a, 130b, 130c, 130d, 130e, and 130f are vertically stacked in the cavities CAV of the substrate 100 and the first to third upper semiconductor chips 410, 420, and 430 are mounted on the first redistribution substrate 300, it may be possible to increase the integration density of the semiconductor package. Furthermore, since the first and second redistribution substrates 300 and 200 connected to the lower semiconductor chips 130a, 130b, 130c, 130d, 130e, and 130f are disposed on the first and second surfaces 100a and 100b, respectively, of the substrate 100 and the bridge chips 330a and 330b are disposed in the first redistribution substrate 300, the first to third upper semiconductor chips 410, 420, and 430 may be effectively connected to the lower semiconductor chips 130a, 130b, 130c, 130d, 130e, and 130f.

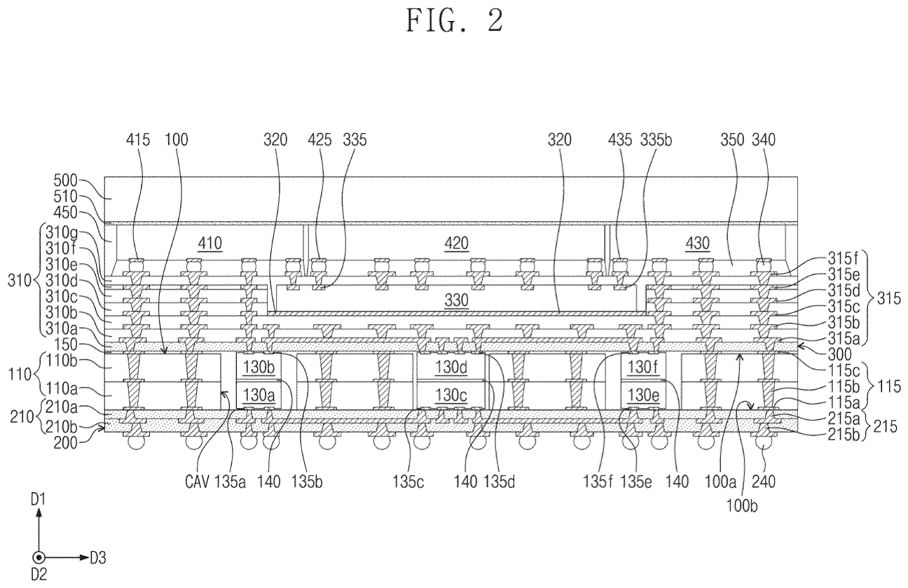

FIG. 2 is a cross-sectional view illustrating a semiconductor package according to one or more embodiments of the disclosure. In the following description, an element previously described with reference to FIG. 1 may be identified by the same reference number without repeating an overlapping description thereof, for concise description.

Referring to FIG. 2, a semiconductor package according to one or more embodiments of the disclosure may include the substrate 100, the first redistribution substrate 300, and the second redistribution substrate 200. The semiconductor package may include the lower semiconductor chips 130a, 130b, 130c, 130d, 130e, and 130f, the first to third upper semiconductor chip 410, 420, and 430, and the bridge chip 330, which are provided therein.

The bridge chip 330 may be buried in the first redistribution substrate 300 and may be disposed on the stopper metal layer 320. The bridge chip 330 may be electrically connected to the sixth upper conductive pattern 315f of the first redistribution conductive pattern 315. Bridge coupling terminals 335, which are mounted on a top surface of the bridge chip 330, may be connected to the sixth upper conductive patterns 315f and may be coupled to the first to third upper semiconductor chips 410, 420, and 430. In other words, the bridge chip 330 may electrically connect the first to third upper semiconductor chips 410, 420, and 430 to each other.

When viewed in a plan view, the bridge chip 330 and the stopper metal layer 320 may be partially overlapped with the first to third upper semiconductor chips 410, 420, and 430. In one or more embodiments, the stopper metal layer 320 may be extended in the third direction D3 and may be placed below the first to third upper semiconductor chips 410, 420, and 430.

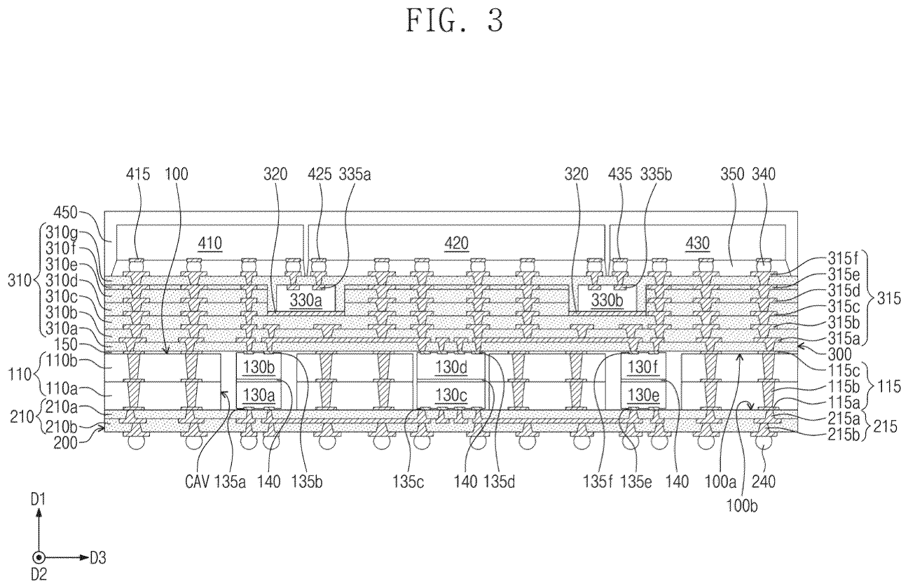

FIG. 3 is a cross-sectional view illustrating a semiconductor package according to one or more embodiments of the disclosure. In the following description, an element previously described with reference to FIG. 1 may be identified by a similar or identical reference number without repeating an overlapping description thereof.

Referring to FIG. 3, the heat-dissipation plate 500 and the thermally conductive element 510 of FIG. 1 may be omitted. The mold layer 450 may cover the top surfaces of the first to third upper semiconductor chips 410, 420, and 430. In one or more embodiments, an upper portion of the mold layer 450 may be ground in such a way that the top surface of the mold layer 450 are coplanar with the top surfaces of the first to third upper semiconductor chips 410, 420, and 430. The top surfaces of the first to third upper semiconductor chips 410, 420, and 430 may be exposed to the outside.

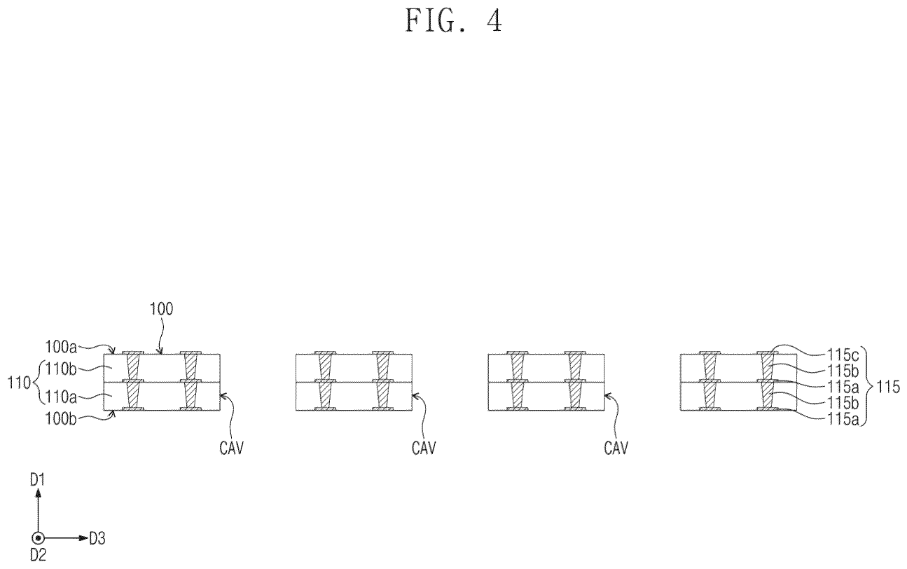

FIGS. 4 to 15 are cross-sectional views illustrating a method of fabricating a semiconductor package, according to one or more embodiments of the disclosure.

Referring to FIG. 4, the substrate 100 having the first surface 100a and the second surface 100b, which are opposite to each other, may be provided. The substrate 100 may include the cavities CAV, the insulating patterns 110, and the interconnection patterns 115 in the insulating patterns 110. The cavities CAV may be spaced apart from each other in the third direction D3.

The interconnection patterns 115 may include the interconnection line 115a, the interconnection via 115b, and the interconnection pad 115c. In one or more embodiments, the interconnection patterns 115 may be a multi-layered structure, in which two or more interconnection lines 115a or two or more the interconnection vias 115b are alternately stacked. The interconnection pad 115c may be a protruding patter, which is placed on the second insulating pattern 110b.

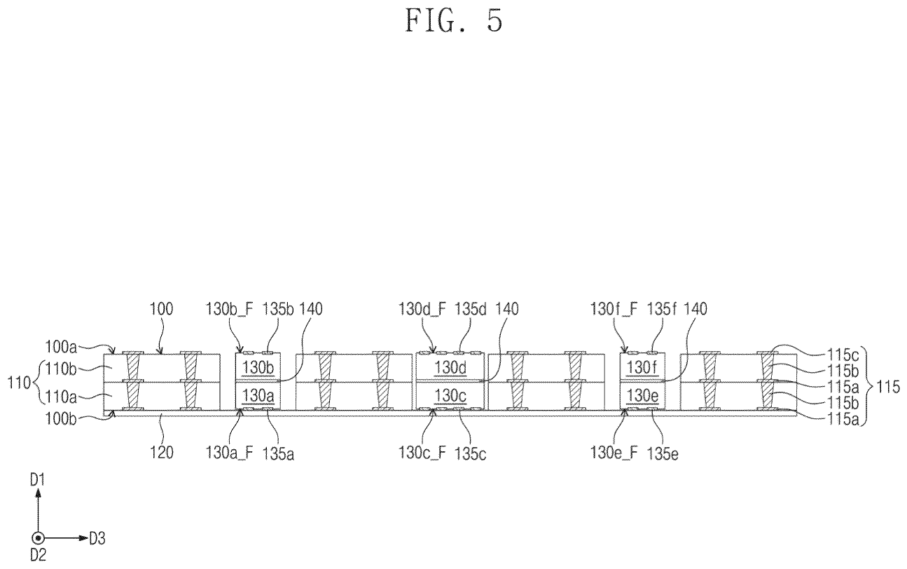

Referring to FIG. 5, a lower polymer layer 120 may be attached to the second surface 100b of the substrate 100. The first, third, and fifth semiconductor chips 130a, 130c, and 130e may be disposed on the lower polymer layer 120 to be placed in the cavities CAV, respectively. The front surfaces 130a_F, 130c_F, and 130e_F of the first, third, and fifth semiconductor chips 130a, 130c, and 130e may face downward. In other words, the first, third, and fifth semiconductor chips 130a, 130c, and 130e may be provided in a face-down manner, and the first, third, and fifth lower chip pads 135a, 135c, and 135e may be in contact with the lower polymer layer 120. Next, the adhesive layer 140 may be formed on the rear surfaces of the first, third, and fifth semiconductor chips 130a, 130c, and 130e.

The second, fourth, and sixth semiconductor chips 130b, 130d, and 130f may be disposed on the first, third, and fifth semiconductor chips 130a, 130c, and 130e, respectively. The rear surfaces of the second, fourth, and sixth semiconductor chips 130b, 130d, and 130f may be attached to the rear surfaces of the first, third, and fifth semiconductor chips 130a, 130c, and 130e using the adhesive layer 140.

The second, fourth, and sixth semiconductor chips 130b, 130d, and 130f may be disposed in such a way that the front surfaces 130b_F, 130d_F, and 130f_F face upward. In other words, the second, fourth, and sixth semiconductor chips 130b, 130d, and 130f may be provided in a face-up manner, and the second, fourth, and sixth lower chip pads 135b, 135d, and 135f may be exposed to an upper outer space.

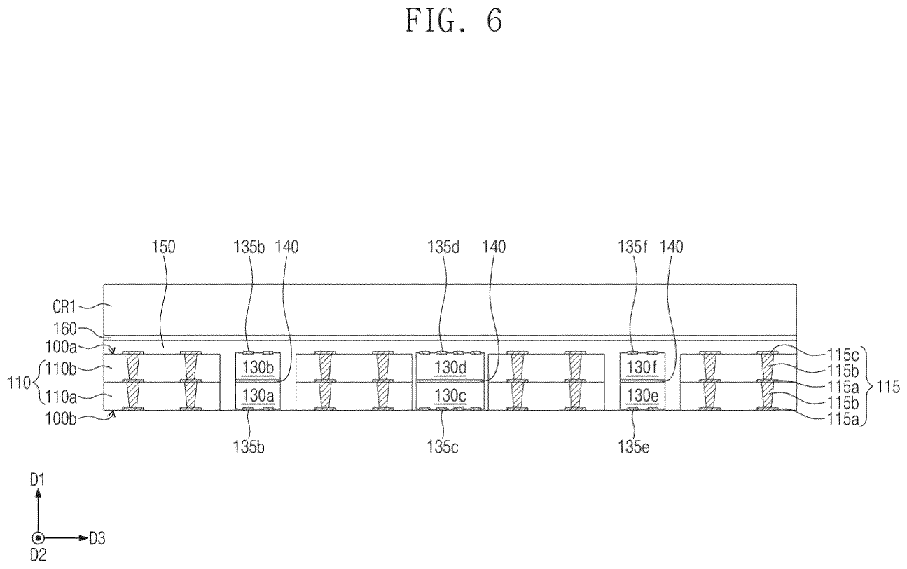

Referring to FIG. 6, the gapfill insulating layer 150 may be formed to fill the cavities CAV and cover the substrate 100 and the lower semiconductor chips 130a, 130b, 130c, 130d, 130e, and 130f. A polishing process may be performed to planarize a top surface of the gapfill insulating layer 150. The polishing process may include a planarization process, such as a mechanical polishing (e.g., chemical mechanical polishing (CMP) process).

An upper adhesion film 160 and a first carrier substrate CR1 may be sequentially formed on the gapfill insulating layer 150. The upper adhesion film 160 may be used to attach the first carrier substrate CR1 to the gapfill insulating layer 150. Next, the lower polymer layer 120 of FIG. 5 may be removed by a grinding process.

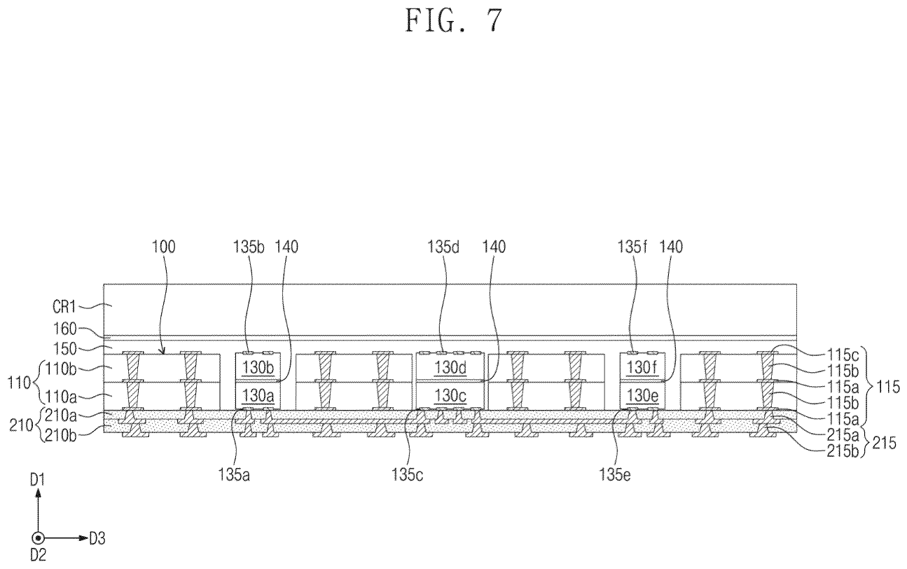

Referring to FIG. 7, the second redistribution insulating layer 210 and the second redistribution conductive patterns 215 may be formed below the substrate 100 and the gapfill insulating layer 150. In one or more embodiments, the formation of the second redistribution insulating layer 210 and the second redistribution conductive patterns 215 may include providing a photosensitive polyimide film on the bottom surface of the substrate 100 to form a first lower insulating layer 210a, forming an opening in the first lower insulating layer 210a to expose the lowermost interconnection line 115a, and performing a metal line process to form a lower via pattern filling the opening of the first lower insulating layer 210a and a lower line pattern extending along a top surface of the first lower insulating layer 210a. Thereafter, the operations may be repeated to form the second lower insulating layer 210b and the second lower conductive patterns 215b below the first lower insulating layer 210a and the first lower conductive patterns 215a.

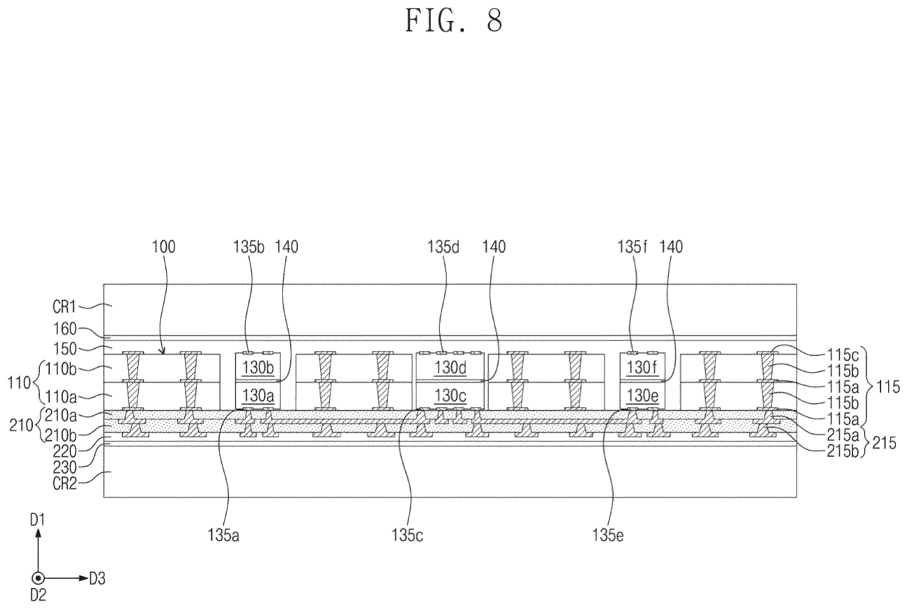

Referring to FIG. 8, a third lower insulating layer 220 may be formed below the second lower insulating layer 210b to cover the second lower conductive patterns 215b. The third lower insulating layer 220 may include a material different from the first and second lower insulating layers 210a and 210b. For example, the third lower insulating layer 220 may include a silicon-based insulating material.

A lower adhesion film 230 and a second carrier substrate CR2 may be provided below the third lower insulating layer 220. The second carrier substrate CR2 may be attached to the third lower insulating layer 220 through the lower adhesion film 230.

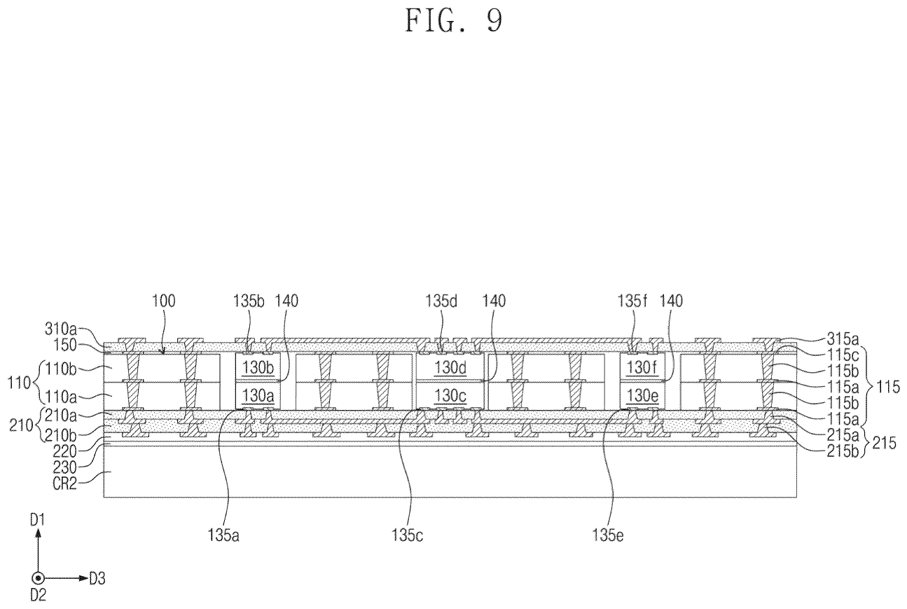

Referring to FIG. 9, the upper adhesion film 160 of FIG. 8 and the first carrier substrate CR1 of FIG. 8 may be removed. Next, the gapfill insulating layer 150 may be ground to expose top surfaces of the interconnection pads 115c and the second, fourth, and sixth lower chip pads 135b, 135d, and 135f of the second, fourth, and sixth lower semiconductor chips 130b, 130d, and 130f.

The first upper insulating layer 310a and the first upper conductive patterns 315a may be formed to cover the exposed top surfaces of the interconnection pads 115c and the second, fourth, and sixth lower chip pads 135b, 135d, and 135f. The formation of the first upper insulating layer 310a and the first upper conductive patterns 315a may include providing a photosensitive polyimide film on the top surface of the substrate 100 to form the first upper insulating layer 310a, forming an opening in the first upper insulating layer 310a to expose the interconnection pad 115c and lower chip pads 135b, 135d, and 135f, and performing a metal line process to form an upper via pattern filling the opening of the first upper insulating layer 310a and an upper line pattern extending along a top surface of the first upper insulating layer 310a.

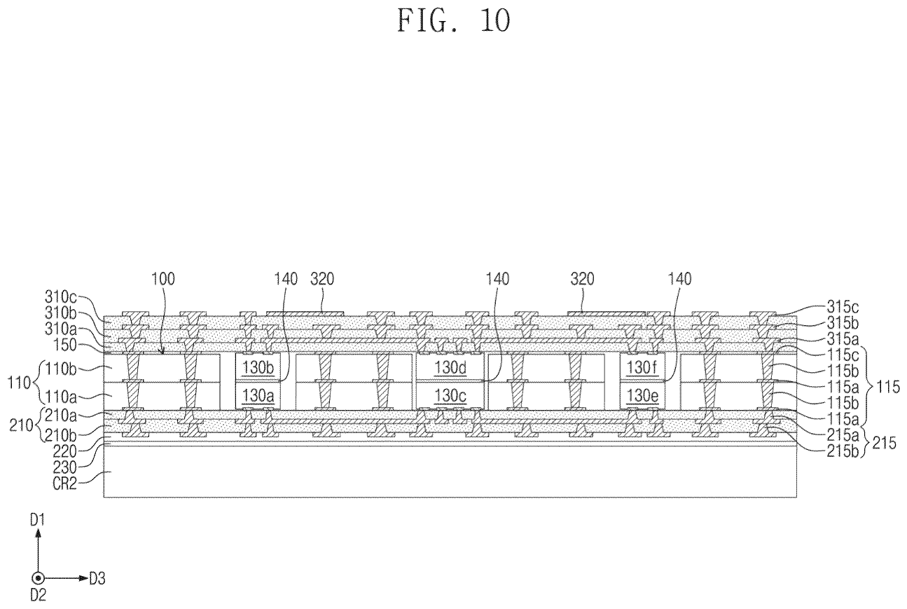

Referring to FIG. 10, the second and third upper insulating layers 310b and 310c and the second and third upper conductive patterns 315b and 315c may be formed on the first upper insulating layer 310a and the first upper conductive patterns 315a. The second and third upper insulating layers 310b and 310c and the second and third upper conductive patterns 315b and 315c may be formed by repeating the afore-described process of forming the first upper insulating layer 310a and the first upper conductive patterns 315a.

The stopper metal layers 320 may be formed on the third upper insulating layer 310c. The stopper metal layers 320 may be formed using a plating method (e.g., an electroplating method, an electroless plating method, or an immersion plating method). The stopper metal layers 320 may be formed to be spaced apart from each other in the third direction D3.

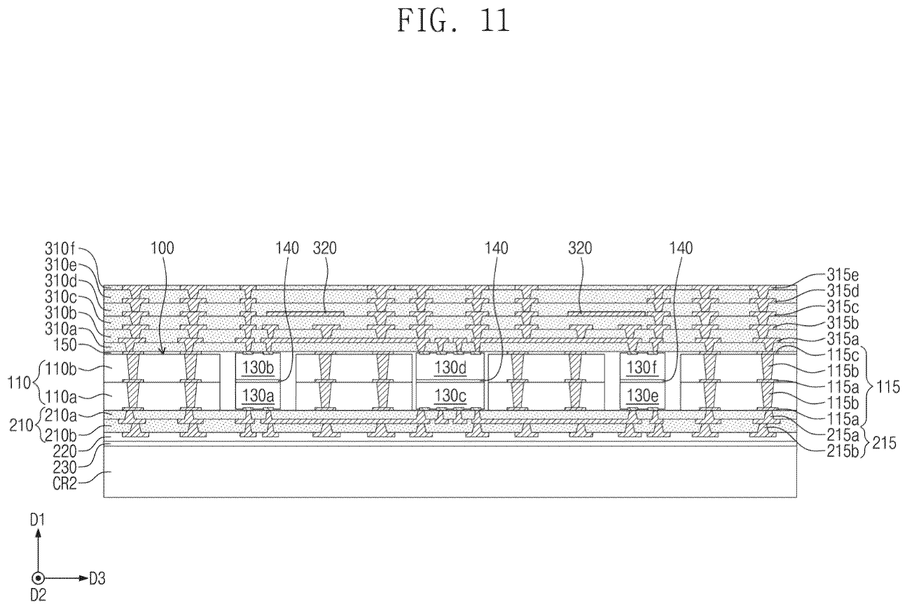

Referring to FIG. 11, the fourth to sixth upper insulating layers 310d, 310e, and 310f and the fourth and fifth upper conductive patterns 315d and 315e may be formed. The fourth and fifth upper insulating layers 310d and 310e and the fourth and fifth upper conductive patterns 315d and 315e may be formed by repeating the afore-described process of forming the first upper insulating layer 310a and the first upper conductive patterns 315a. The formation of the sixth upper insulating layer 310f may include depositing a photosensitive polyimide film on the fifth upper insulating layer 310e to cover the fifth upper conductive patterns 315e and grinding the photosensitive polyimide film to expose top surfaces of the fifth upper conductive patterns 315e.

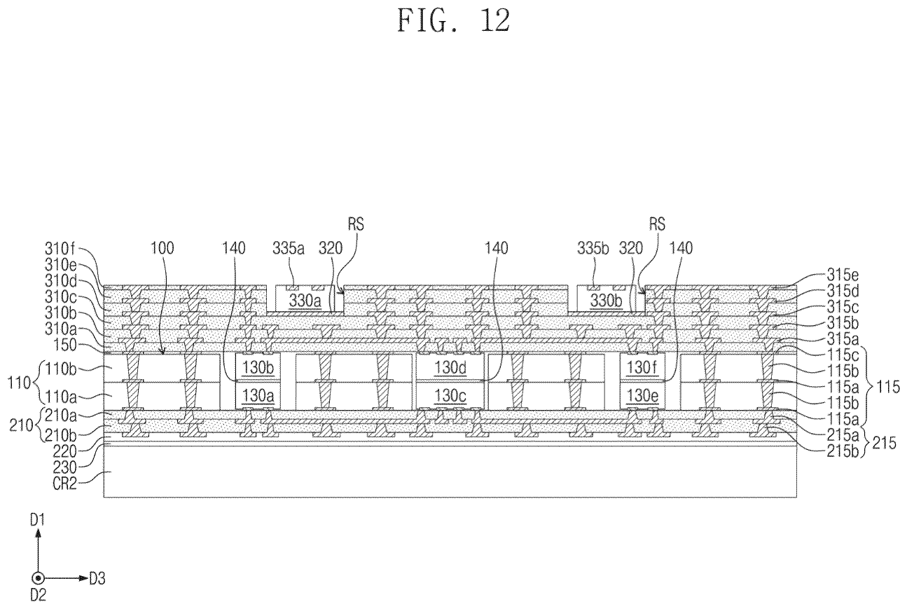

Referring to FIG. 12, recesses RS may be formed by removing portions of the fourth to sixth upper insulating layers 310d, 310e, and 310f to expose top surfaces of the stopper metal layers 320. A width of the recess RS may be substantially equal to a width of the stopper metal layer 320, when measured in a horizontal direction (e.g., the second or third direction D2 or D3). A laser drilling method may be used in the operation of removing the portions of the fourth to sixth upper insulating layers 310d, 310e, and 310f, but the disclosure is not limited to this example.

In the recesses RS, the first and second bridge chips 330a and 330b may be disposed on the stopper metal layers 320. The first and second bridge chips 330a and 330b may be disposed in the recesses RS, respectively. The first and second bridge coupling terminals 335a and 335b may be disposed on the top surfaces of the first and second bridge chips 330a and 330b.

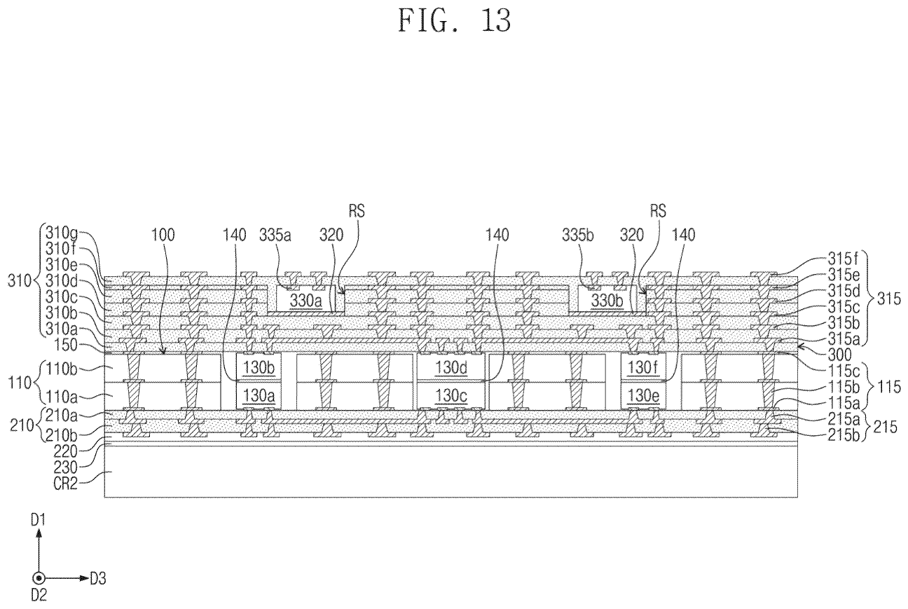

Referring to FIG. 13, the seventh upper insulating layer 310g and the sixth upper conductive patterns 315f may be formed on the sixth upper insulating layer 310f and the first and second bridge chips 330a and 330b. The seventh upper insulating layer 310g may cover the side and top surfaces of the first and second bridge chips 330a and 330b and may fill remaining spaces of the recesses RS. The seventh upper insulating layer 310g and the sixth upper conductive patterns 315f may be formed by repeating the afore-described process of forming the first upper insulating layer 310a and the first upper conductive patterns 315a.

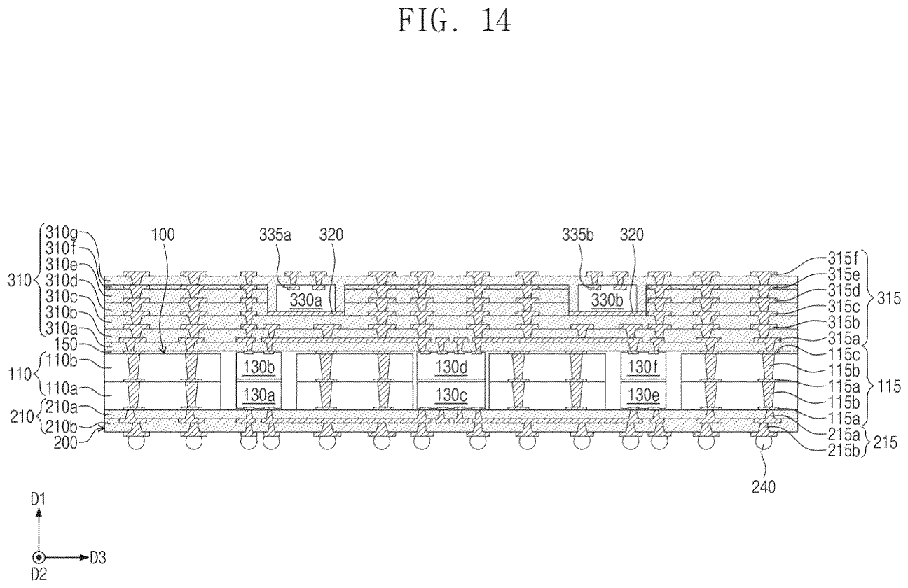

Referring to FIG. 14, the lower adhesion film 230 of FIG. 13 and the second carrier substrate CR2 of FIG. 13 may be removed. The third lower insulating layer 220 on the second lower insulating layer 210b of FIG. 13 may be removed to expose the second lower conductive patterns 215b.

A laser ablation process may be performed to additionally remove portions of the second lower conductive patterns 215b. Accordingly, adjacent ones of the second lower conductive patterns 215b may be electrically disconnected from each other. As a result of the laser ablation process, the second redistribution substrate 200 may be formed. Next, the outer coupling terminal 240, which are directly connected to the second lower conductive patterns 215b, may be formed under the second redistribution substrate 200.

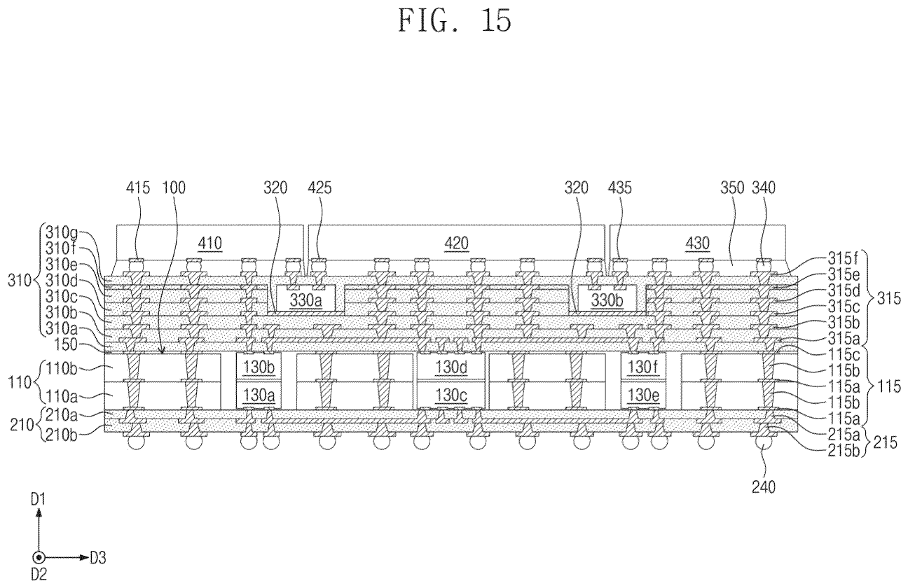

Referring to FIG. 15, the conductive bumps 340, which are connected to the sixth upper conductive patterns 315f, may be attached to the first redistribution substrate 300. The first to third upper semiconductor chips 410, 420, and 430 may be disposed on the conductive bumps 340, and the first to third upper chip pads 415, 425, and 435 may be connected to the conductive bumps 340. Next, the under-fill layer 350 may be formed between the first to third upper semiconductor chips 410, 420, and 430 and the first redistribution substrate 300. In one or more embodiments, the under-fill layer 350 may be formed by a capillary under-fill method.

Referring back to FIG. 1, the mold layer 450 may be formed on the first redistribution substrate 300 to cover side surfaces of the first to third upper semiconductor chips 410, 420, and 430. The formation of the mold layer 450 may include forming a molding layer to cover the first to third upper semiconductor chips 410, 420, and 430 and grinding the molding layer to expose top surfaces of the first to third upper semiconductor chips 410, 420, and 430.

The thermally conductive element 510 and the heat-dissipation plate 500 may be sequentially disposed on the mold layer 450 and the first to third upper semiconductor chips 410, 420, and 430.

According to one or more embodiments of the disclosure, a plurality of semiconductor chips may be mounted in a cavity of a substrate, and a plurality of semiconductor chips may be connected to redistribution substrates, which are respectively placed on first and second surfaces of the substrate. In addition, the semiconductor chips may be stacked on the redistribution substrate. Thus, it may be possible to increase an integration density of a semiconductor package and improve an electric performance of the semiconductor package.

Furthermore, a bridge chip, on which a fine circuit is formed, may be buried in the redistribution substrate, and the semiconductor chips may be connected to each other through the bridge chips. Thus, a semiconductor package with improved electric reliability may be provided.

While one or more embodiments of the disclosure have been particularly shown and described, it will be understood by one of ordinary skill in the art that variations in form and detail may be made therein without departing from the spirit and scope of the attached claims.

What is claimed is:

1. A semiconductor package comprising:
a substrate comprising a first surface and a second surface, wherein the second surface is opposite to the first surface, and wherein the substrate further comprises a first cavity extending from the first surface to the second surface;
a first lower semiconductor chip and a second lower semiconductor chip, wherein the first and the second lower semiconductor chips are vertically stacked in the first cavity;
a first redistribution substrate on the first surface of the substrate;
a first upper semiconductor chip on the first redistribution substrate;
a second upper semiconductor chip on the first redistribution substrate and horizontally spaced apart from the first upper semiconductor chip; and
a first bridge chip in the first redistribution substrate, wherein the first bridge chip connects the first upper semiconductor chip to the second upper semiconductor chip,
wherein the first lower semiconductor chip is spaced apart from the first redistribution substrate, and
wherein the second lower semiconductor chip is directly connected to the first redistribution substrate.

2. The semiconductor package of claim 1, wherein the first redistribution substrate comprises:
a first redistribution insulating layer on the first surface; and
a first redistribution conductive pattern penetrating at least a portion of the first redistribution insulating layer,
wherein the first redistribution conductive pattern connects the first bridge chip to the first upper semiconductor chip and connects the first bridge chip to the second upper semiconductor chip.

3. The semiconductor package of claim 2, wherein the first redistribution conductive pattern connects the first upper semiconductor chip to the second lower semiconductor chip.

4. The semiconductor package of claim 2, further comprising a stopper metal layer in the first redistribution insulating layer, wherein the stopper metal layer is on at least a portion of a bottom surface of the first bridge chip.

5. The semiconductor package of claim 1, further comprising a third lower semiconductor chip and a fourth lower semiconductor chip,
wherein the substrate further comprises a plurality of cavities extending from the first surface to the second surface, the plurality of cavities including the first cavity, and
wherein the third and the fourth lower semiconductor chips are vertically stacked in a second cavity among the plurality of cavities, wherein the second cavity is horizontally spaced apart from the first cavity.

6. The semiconductor package of claim 5,
wherein the third lower semiconductor chip is spaced apart from the first redistribution substrate, and
wherein the fourth lower semiconductor chip is directly connected to the first redistribution substrate.

7. The semiconductor package of claim 1, wherein the substrate further comprises:
a first insulating pattern;
a second insulating pattern on the first insulating pattern and adjacent to the first redistribution substrate; and
an interconnection pattern penetrating the first and the second insulating patterns.

8. The semiconductor package of claim 7,
wherein the interconnection pattern comprises an interconnection via penetrating each of the first and the second insulating patterns, and
wherein a width of the interconnection via increases as a distance to the first redistribution substrate decreases.

9. The semiconductor package of claim 1, further comprising:
a third upper semiconductor chip on the first redistribution substrate and horizontally spaced apart from the first and the second upper semiconductor chips; and
a second bridge chip in the first redistribution substrate, wherein the second bridge chip connects the second upper semiconductor chip to the third upper semiconductor chip.

10. The semiconductor package of claim 1, further comprising a third upper semiconductor chip,
wherein the third upper semiconductor chip is on the first redistribution substrate and is horizontally spaced apart from the first and the second upper semiconductor chips, and
wherein the first bridge chip connects the first upper semiconductor chip to the third upper semiconductor chip.

11. The semiconductor package of claim 1, further comprising a second redistribution substrate on the second surface of the substrate,
wherein the second redistribution substrate is connected to the first lower semiconductor chip.

12. The semiconductor package of claim 11, further comprising an outer coupling terminal directly connected to the second redistribution substrate.

13. A semiconductor package comprising:
a substrate comprising a first surface and a second surface, wherein the second surface is opposite to the first surface, and wherein the substrate further comprises a first cavity extending from the first surface to the second surface;
a first lower semiconductor chip and a second lower semiconductor chip, wherein the first and the second lower semiconductor chips are vertically stacked in the first cavity;
a first redistribution substrate on the first surface of the substrate;
a first upper semiconductor chip on the first redistribution substrate;
a second upper semiconductor chip on the first redistribution substrate and horizontally spaced apart from the first upper semiconductor chip;
a bridge chip in the first redistribution substrate, wherein the bridge chip connects the first upper semiconductor chip to and the second upper semiconductor chip; and
a second redistribution substrate on the second surface.

14. The semiconductor package of claim 13,
wherein each of the first and the second lower semiconductor chips has a front surface and a rear surface,
wherein for each of the first and the second lower semiconductor chips the rear surface is opposite to the front surface,
wherein the front surface of the first lower semiconductor chip faces the second redistribution substrate, and
wherein the front surface of the second lower semiconductor chip faces the first redistribution substrate.

15. The semiconductor package of claim 14, further comprising an adhesive layer between the rear surface of the first lower semiconductor chip and the rear surface of the second lower semiconductor chip.

16. The semiconductor package of claim 13, further comprising a third lower semiconductor chip and a fourth lower semiconductor chip,
wherein the substrate further comprises a plurality of cavities extending from the first surface to the second surface, the plurality of cavities including the first cavity,
wherein the third and the fourth lower semiconductor chips are vertically stacked in a second cavity among the plurality of cavities,
wherein the second cavity is horizontally spaced apart from the first cavity, and
wherein the second redistribution substrate is connected to the first lower semiconductor chip and the third lower semiconductor chip.

17. The semiconductor package of claim 13,
wherein the substrate further comprises:
a first insulating pattern adjacent to the second redistribution substrate;
a second insulating pattern on the first insulating pattern and adjacent to the first redistribution substrate; and
an interconnection pattern penetrating the first and the second insulating patterns, and
wherein the interconnection pattern is connected to the first redistribution substrate and the second redistribution substrate.

18. The semiconductor package of claim 17,
wherein a side surface of the first insulating pattern faces a side surface of the first lower semiconductor chip, and
wherein a side surface of the second insulating pattern faces a side surface of the second lower semiconductor chip.

19. The semiconductor package of claim 13, further comprising:
a heat dissipation plate on the first upper semiconductor chip and the second upper semiconductor chip; and
an outer coupling terminal connected to the second redistribution substrate.

20. A semiconductor package comprising:
a substrate comprising a first surface and a second surface, wherein the second surface is opposite to the first surface, and wherein the substrate further comprises a cavity extending from the first surface to the second surface;
a first lower semiconductor chip and a second lower semiconductor chip, wherein the first and the second lower semiconductor chips are vertically stacked in the cavity;
a first redistribution substrate on the first surface of the substrate and on the second lower semiconductor chip;
a second redistribution substrate on the second surface of the substrate and on the first lower semiconductor chip;
a gapfill insulating layer between the substrate and the first redistribution substrate and between the substrate and the first and the second lower semiconductor chips;
a first upper semiconductor chip on the first redistribution substrate;
a second upper semiconductor chip on the first redistribution substrate and horizontally spaced apart from the first upper semiconductor chip;
conductive bumps connecting the first upper semiconductor chip to the first redistribution substrate and connecting the second upper semiconductor chip to the first redistribution substrate;
a bridge chip in the first redistribution substrate, wherein the bridge chip connects the first upper semiconductor chip to the second upper semiconductor chip; and
a mold layer on the first redistribution substrate and on at least a portion of a side surface of the first upper semiconductor chip and at least a portion of a side surface of the second upper semiconductor chip.
